(19) United States
(12) Patent Application Publication
(10) Pub. No.: US 2008/0173995 A1
(43) Pub. Date: Jul. 24, 2008

(54) Memory card and manufacturing method of the same

(75) Inventors: Bunshi Kuratomi, Tokyo (JP); Fukumi Shimizu, Tokyo (JP); Michiaki Sugiyama, Tokyo (JP); Atsushi Fujishima, Tokyo (JP); Tamaki Wada, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/898,456

(22) Filed: Sep. 12, 2007

(30) Foreign Application Priority Data
Sep. 29, 2006 (JP) 2006-266453

(51) Int. Cl. H01L 23/48; H01L 21/56

(52) U.S. Cl. 257/679; 438/107; 257/E23.01; 257/E21.502

(57) ABSTRACT

There is a need to provide a large capacity memory card for a portable communication device. A memory card 1 includes: a wiring board 2 mainly composed of a glass epoxy resin; multiple semiconductor chips (3C and 3F) mounted on a main surface of the memory card 1; and a mold resin 4 for encapsulating the wiring board 2 and the semiconductor chips (3C and 3F). The mold resin 4 is made of a thermosetting epoxy resin containing quartz filler. A back surface of the wiring board 2 is not covered with the mold resin 4 and is exposed to a back surface of the memory card 1. The back surface of the wiring board 2 is used to form multiple external connection terminals 7 electrically connected to the semiconductor chips (3C and 3F) . When the memory card 1 is attached to a card slot of a mobile phone, the external connection terminals 7 contact with a connector terminal contained in the card slot. This makes it possible to exchange signals between the memory card 1 and the mobile phone or to supply the power.

### BACKGROUND OF THE INVENTION

The present invention relates to a memory card and its manufacturing technology. More specifically, the invention relates to a technology effectively applicable to a small thin memory card attached to a card slot of a portable communication device.

A recent mobile phone is provided with not only a telephone function but also the other functions such as network connection, e-mail transmission, image capturing, and navigation. Most recently, there is a trend of providing the security function such as a contactless IC card.

The advent of multifunctional mobile phones necessitates development of various cards attached to a memory card slot of a mobile phone so as to provide smaller, thinner, and more multifunctional cards.

Japanese patent laid-open No. 2005-339496 (Patent Document 1) discloses a small, large-capacity memory card (multifunction memory card) having the memory and security functions for mobile phones.

The memory card disclosed in Japanese patent laid-open No. 2005-339496 includes a card body and a cap for housing it. The card body includes: a wiring board using a glass epoxy resin; multiple semiconductor chips layered over the wiring board; and a mold resin for encapsulating the semiconductor chips. The semiconductor chip and the wiring board are electrically coupled through a wire. A thermosetting epoxy resin containing a quartz filler is used for the mold resin that encapsulates the semiconductor chips.

A molded thermoplastic resin is used for the cap for housing the card body. One end of the cap is provided with a convex portion that functions as a positioning mechanism for correctly inserting the memory card into a mobile phone slot. On its reverse side, the cap is provided with a recess sized approximately equal to the card body. The card body is placed inside the recess with a main surface (chip mounting surface) of the wiring board directed inward. The card body is attached to the cap with an adhesive. That is, the card body is exposed from the cap only on the reverse side of the wiring board. The other parts of the card body are covered with the cap. A depth of the cap recess is approximately equal to a thickness of the card body. The reverse side of the cap is approximately level with the reverse side of the wiring board. Multiple external connection terminals are formed on the reverse side of the wiring board. When the memory card is attached to the mobile phone slot, the external connection terminals contact with a connector terminal contained in the slot to exchange signals or supply the power.

The memory card according to the above-mentioned construction is very small and thin. It is sized to 16 mm on the long side, 12.5 mm on the short side, and 1.2 mm thick (1.6 mm thick only at the part forming the convex portion).

The manufacture of the above-mentioned memory card uses a large wiring board that has an area as large as dozens of times the area of the wiring board. The large wiring board contains multiple units of wiring patterns needed for the wiring board in a matrix. To manufacture the memory card, multiple semiconductor chips are layered in each unit of the large wiring board. A wire is used to electrically connect the wiring pattern of the large wiring board with each semiconductor chip. The large wiring board is set in a mold resin die made of an upper die and a lower die to encapsulate all the semiconductor chips with the mold resin at a time. A dicing blade is then used to cut and separate the large wiring board and the mold resin into units to produce many card bodies each of which has the above-mentioned outside dimension and is shaped into a rectangular parallelepiped. On the other hand, a thermoplastic resin is injected into another resin die different from the above-mentioned mold resin die to form a cap. Thereafter, the card body is placed in a cap recess. Both are then bonded with an adhesive.

### SUMMARY OF THE INVENTION

The memory card described in Japanese patent laid-open No. 2005-339496 includes the card body and the cap for housing the card body. The memory card thickness depends on the sum of the card body thickness and the cap thickness. The cap thickness places a limitation on the card body thickness. This limits the number of semiconductor chips when they are mounted on the wiring board in piles.

After the card body and the cap are formed independently, there is a need for a process to place the card body in the cap. This complicates the memory card manufacturing process.

It is therefore an object of the present invention to provide a technology of providing a large-capacity memory card for portable communication devices.

It is another object of the present invention to provide a technology of simplifying a manufacturing process of the memory card for portable communication devices.

These and other objects and novel features of the invention may be readily ascertained by referring to the following description and appended drawings.

The following briefly summarizes representative aspects of the present invention disclosed in the application concerned.

A memory card according to the invention includes: a wiring board; a plurality of memory chips layered over a main surface of the wiring board; a plurality of external connection terminals that are formed over a back surface of the wiring board and are electrically coupled with the memory chips; and a mold resin that encapsulates the main surface of the wiring board and the memory chips, covers a side of the wiring board, and exposes a back surface of the wiring board.

A manufacturing method for the above-mentioned memory card according to the invention includes the steps of: (a) preparing a large wiring board forming a plurality of units of patterns needed for the wiring board; (b) mounting the memory chips on the respective units of the large wiring board; (c) after the step (b), attaching the large wiring board to a mold resin die, injecting a melted resin into a plurality of cavities provided for the mold resin die, and thereby forming the mold resin for encapsulating the memory chips correspondingly to units; and (d) after the step (c), cutting and separating the mold resin and part of the large wiring board encapsulated by the mold resin from the large wiring board. After the step (d), the mold resin is formed so as to cover a side of the wiring board and expose a back surface of the same.

The following describes an effect resulting from the representative aspects of the present invention disclosed in the application concerned.

A large capacity memory card can be provided.

A memory card manufacturing process can be simplified.

### BRIEF DESCRIPTION OF THE DRAWINGS

FIG. 1 is a plan view showing an external view of a memory card according to an embodiment of the present invention;

FIG. 2 is a plan view showing an internal structure of the memory card according to the embodiment of the present invention;

FIG. 3 is a plan view showing an external view of the memory card according to the embodiment of the present invention;

FIG. 4 is a cross sectional view taken along line A-A of FIG. 1;

FIG. 5 is a cross sectional view taken along line B-B of FIG. 1;

FIG. 6 is a schematic diagram showing an example of functions of external connection terminals in the memory card according to the embodiment of the present invention;

FIG. 7 is a schematic diagram showing another example of functions of external connection terminals in the memory card according to the embodiment of the invention;

FIG. 8 is a plan view showing a large wiring board used for manufacture of the memory card according to the embodiment of the invention;

FIG. 9 is a plan view of a critical portion showing a manufacturing method of the memory card according to the embodiment of the invention;

FIG. 10 is a cross sectional view taken along line C-C of FIG. 9;

FIG. 11 is a sectional view of a critical portion showing the manufacturing method of the memory card according to the embodiment of the invention;

FIG. 12 is a plan view of a critical portion showing the manufacturing method of the memory card according to the embodiment of the invention;

FIG. 13 is a sectional view of a critical portion showing the manufacturing method of the memory card according to the embodiment of the invention;

FIG. 14 is a sectional view of a critical portion showing a mold resin die used for the manufacturing method of the memory card according to the embodiment of the invention;

FIG. 15 is a plan view of a critical portion showing the manufacturing method of the memory card according to the embodiment of the invention;

FIG. 16 is a schematic diagram showing a method of inserting the memory card according to the embodiment of the invention into a connector; FIG. 17 is a schematic diagram showing the method of inserting the memory card according to the embodiment of the invention into a connector; FIG. 18 shows surface roughness of the memory card manufactured by the method according to the invention;

FIG. 19 shows surface roughness of a memory card manufactured by a conventional method;

FIG. 20 is a sectional view of the memory card according to another embodiment of the invention;

FIG. 21 is a sectional view of the memory card according to still another embodiment of the invention;

FIG. 22 is a sectional view of the memory card according to yet another embodiment of the invention; and

FIG. 23 is a sectional view of the memory card according to still yet another embodiment of the invention.

### DETAILED DESCRIPTION OF THE PREFERRED EMBODIMENTS

Embodiments of the present invention will be described in further detail with reference to the accompanying drawings. Throughout all the drawings used for description of the embodiments, the same parts or components are depicted by the same reference numerals and a detailed description is omitted for simplicity.

### FIRST EMBODIMENT

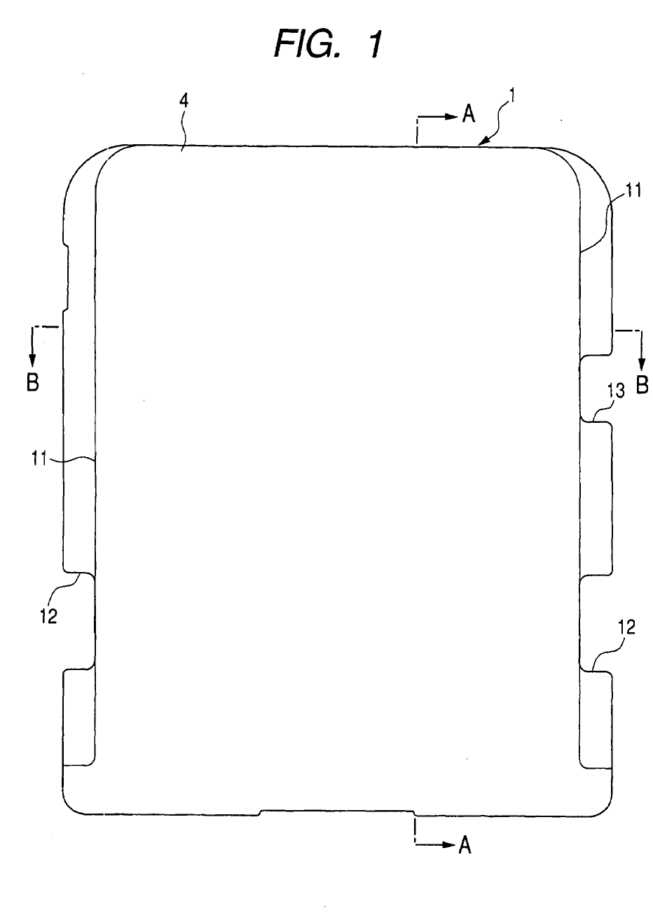

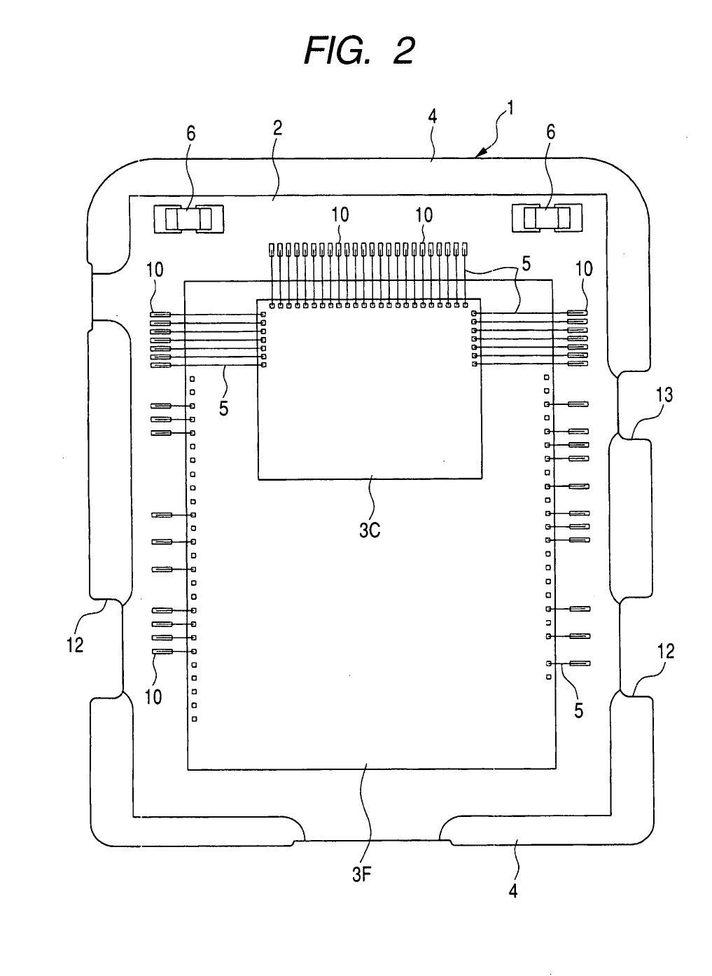

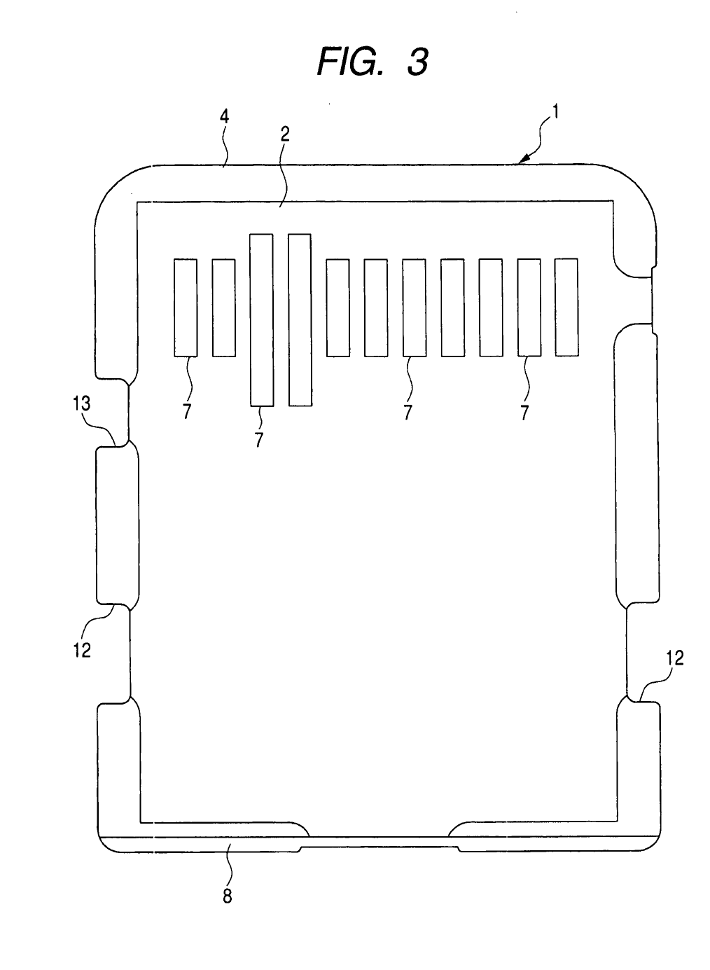

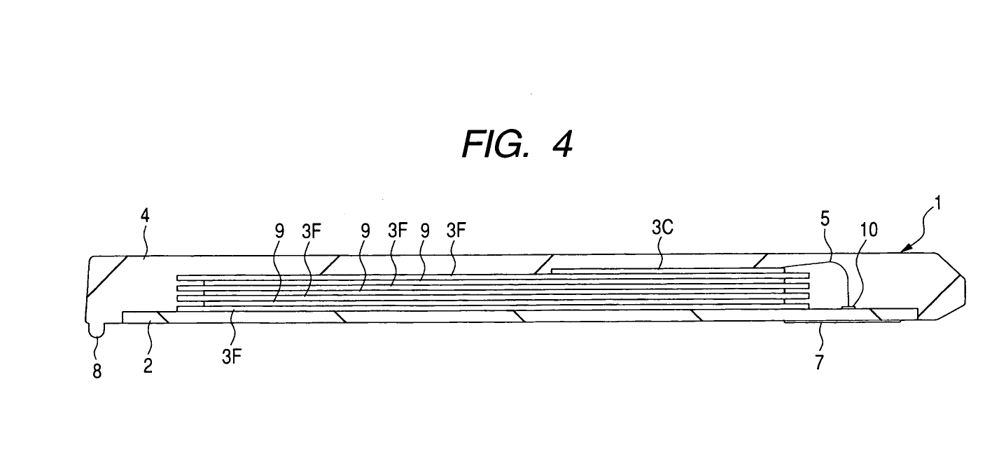

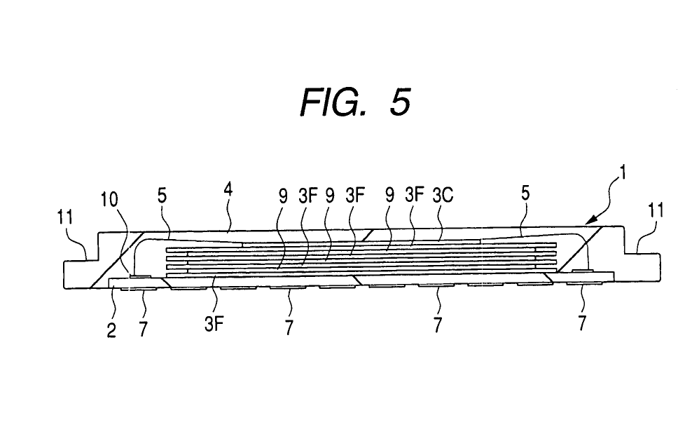

FIG. 1 is a plan view showing an external view (first surface) of a memory card according to the embodiment. FIG. 2 is a plan view showing an internal structure of the memory card according to the embodiment. FIG. 3 is a plan view showing an external view (back surface) of the memory card according to the embodiment. FIG. 4 is a cross sectional view taken along line A-A of FIG. 1. FIG. 5 is a cross sectional view taken along line B-B of FIG. 1.

A memory card 1 according to the embodiment is attached to a card slot of a mobile phone and is designed in compliance with the Memory Stick Micro standard. That is, the memory card 1 has an outside dimension of 16×12.5 mm and is 1.2 mm thick (1.6 mm thick only at a part forming a convex portion)

The memory card 1 includes: a wiring board 2 mainly composed of a glass epoxy resin; multiple semiconductor chips (3C and 3F) mounted on a main surface (first surface) of the memory card 1; and a mold resin 4 for encapsulating the wiring board 2 and the semiconductor chips (3C and 3F) . The mold resin 4 is made of an epoxy resin containing quartz filler and uses a thermosetting epoxy material.

The semiconductor chip 3F includes nonvolatile memory (flash memory) capable of electrically erasing and writing data, for example. The semiconductor chip 3C includes an interface controller. The interface controller has multiple interface control modes. The interface controller controls an external interface operation and a memory interface operation for the memory (semiconductor chip 3F) in a control mode according to an instruction from outside.

The wiring board 2 includes a wiring 10 and a via hole (not shown). The semiconductor chips (3C and 3F) are electrically connected with the wiring 10 through a wire 5 of Au (gold), for example. The main surface of the wiring board 2 is mounted with a passive component such as a chip capacitor 6 as needed. The back surface of the wiring board 2 is not covered with the mold resin 4 and is exposed to the back surface of the memory card 1. Multiple (e.g., 11 or 20 terminals) external connection terminals 7 are formed on the back surface of the wiring board 2 and are electrically connected to the semiconductor chips (3C and 3F) through the via hole, the wiring 10, and the wire 5. When the memory card 1 is attached to the card slot of the mobile phone, the external connection terminals 7 contact with a connector terminal contained in the card slot. This makes it possible to exchange signals between the memory card 1 and the mobile phone or to supply the power.

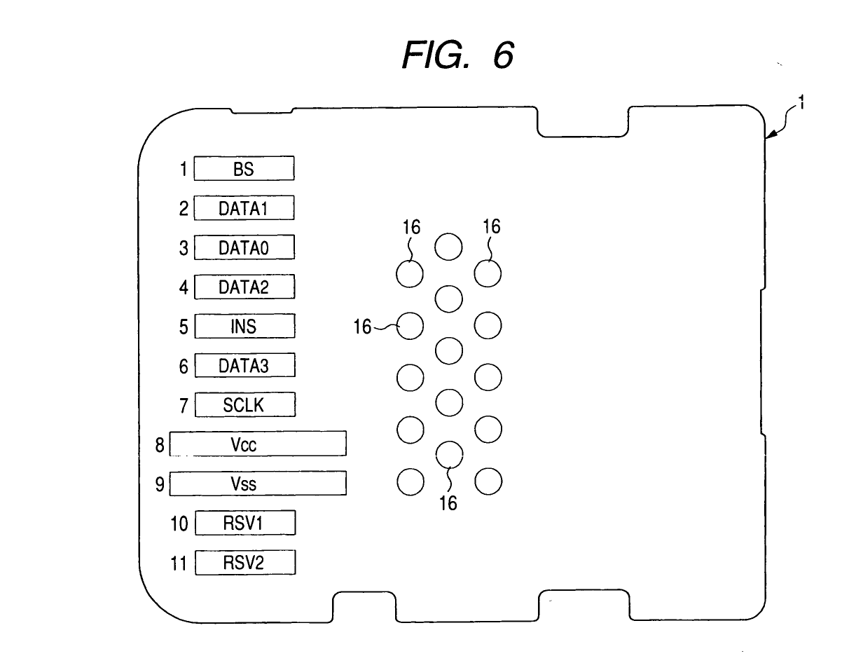

The following describes functions of the external connection terminals 7 with reference to FIG. 6. The eleven external connection terminals 7 are arranged into line with one side of the memory card 1. This side becomes a front edge when the memory card is inserted into the card slot of the mobile phone. Of the external connection terminals 7, an eighth one is a power supply terminal (Vcc) and a ninth one is a ground terminal (Vss) . These terminals have larger areas than the other ones. When the memory card 1 is inserted into the card slot of the mobile phone, the connector terminal in the card slot first contacts with the power supply terminal (Vcc) and the ground terminal (Vss) earlier than the other terminals. When the memory card 1 is removed from the card slot, the other terminals are first disconnected from the connector and thereafter the power supply terminal (Vcc) and the ground terminal (Vss) are disconnected therefrom. That is, the power supply terminal (Vcc) and the ground terminal (Vss) are constructed to reliably contact with the connector terminal.

The eleven external connection terminals 7 are provided with the following functions: the first is BS; the second is DATA1 (data input/output); the third is DATA0 (data input/output); the fourth is DATA2 (data input/output); the fifth is INS; the sixth is DATA3 (data input/output); the seventh is SCLK (clock); the eighth is power supply (Vcc); the ninth is ground (Vss); and the tenth and eleventh are reserved.

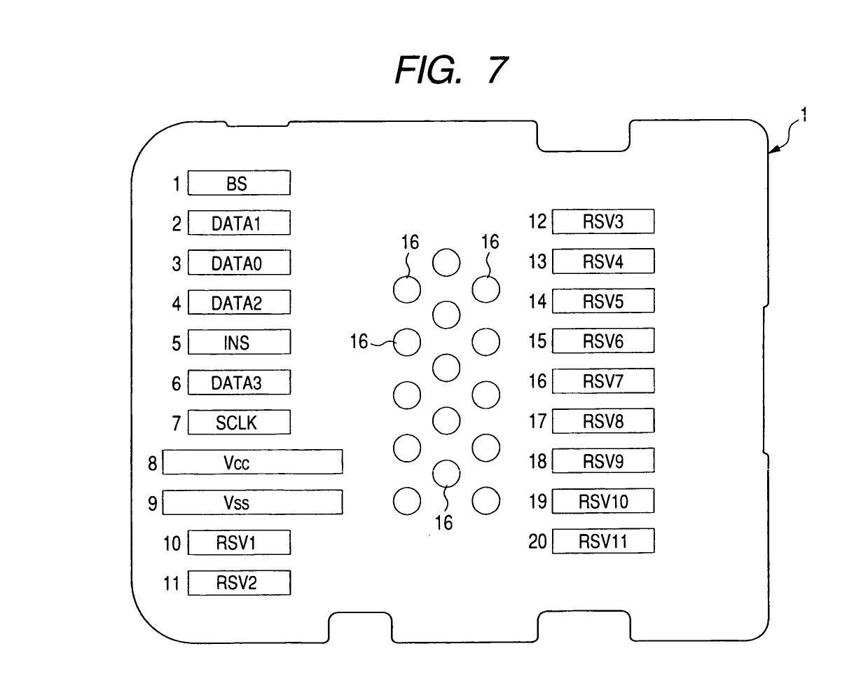

FIG. 7 shows an example of arranging two rows of the 20 external connection terminals 7. The first through eleventh terminals are arranged into line with one side of the memory card 1. This side becomes a front edge when the memory card is inserted into the card slot of the mobile phone. The twelfth through twentieth terminals are arranged into line with another side of the memory card 1. This side becomes a rear edge when the memory card is inserted into the card slot of the mobile phone. The first through eleventh terminals have the same functions as exemplified with reference to FIG. 6. The twelfth through twentieth terminals are reserved.

The reserved terminals as shown in FIGS. 6 and 7 can be used as extension terminals for providing a USB interface or an MMC or serial interface. Another DATA (data input/output) terminal can be added as a Memory Stick PRO interface to provide a multi-bit memory card.

As shown in FIGS. 6 and 7, multiple test terminals 16 are provided approximately at the center of the back surface of the wiring board 2. These test terminals 16 are coupled to the semiconductor chips (3C and 3F) . For example, an electrostatic breakdown may occur to disable operations of the interface controller formed in the semiconductor chip 3C. In such case, the test terminal 16 can be used to directly access the flash memory in the semiconductor chip 3F from outside. Even if the interface controller is destroyed, data in the flash memory, when the data is still retained, can be easily recovered. Normally, the test terminals 16 are covered with an insulating seal or solder resist and cannot be visually identified from outside.

This and the other embodiments describe the memory card 1 having 11 external connection terminals 7. Obviously, the embodiments can be applied to the memory card having 20 external connection terminals 7.

As shown in FIGS. 1 through 3, a projection 8 made of the mold resin 4 is straight formed along one side of the memory card 1. The projection 8 is used as a positioning mechanism for inserting the memory card 1 into a card slot of a mobile phone in a correct orientation.

The memory card 1 according to the embodiment is very small and thin. It is sized to 16 mm on the long side, 12.5 mm on the short side, and 1.2 mm thick (1.6 mm thick only at the part forming the convex portion). Though not shown in the drawings, an insulating label is attached to the first surface (shown in FIG. 1) of the mold resin 4 equivalent to the first surface of the memory card 1. The label contains description of a product name, a manufacturer, a memory capacity, or the like. Instead of using the label, the above description may be directly printed on the first surface of the mold resin.

As shown in FIGS. 4 and 5, five semiconductor chips (3C and 3F) are mounted over the main surface of the wiring board 2. Of the five semiconductor chips (3C and 3F), the one semiconductor chip 3C provides an interface controller. The four semiconductor chips 3F provide memory chips. Of the four semiconductor chips 3F as the memory chips, the bottom one is bonded to the main surface of the wiring board 2 with an adhesive. The remaining three semiconductor chips 3F are alternately layered over the bottom semiconductor chip 3F with three intervening spacer chips 9. The semiconductor chips 3F and the spacer chips 9 are bonded with an adhesive. The semiconductor chip 3C as the interface controller has a smaller area than the semiconductor chip 3F as the memory. The semiconductor chip 3C is placed over the semiconductor chip 3F and is bonded to it with an adhesive. The spacer chip 9 is a dummy chip for ensuring a space for bonding the wire 5 between the lower and upper semiconductor chips 3F. The semiconductor chips (3C and 3F) and the spacer chip 9 are each approximately 90 μm thick.

The memory provided by the semiconductor chip 3F is nonvolatile memory (flash memory) capable of electrically erasing and writing data, for example. A memory cell of the flash memory is constructed as, for example, a stacked-gate structured MISFET having a floating gate or a split-gate structured MISFET including a memory transistor and a selection transistor having an ONO (oxide-nitride-oxide) gate insulating film. The flash memory formed in one semiconductor chip 3F has a storage capacity of four gigabits, for example. The memory card 1 according to the embodiment includes four semiconductor chips 3F and therefore has a storage capacity of two gigabytes, i.e., 4 gigabits×4=16 gigabits.

The interface controller formed in the semiconductor chip 3C has multiple interface control modes. The interface controller controls an external interface operation and a memory interface operation for the memory (semiconductor chip 3F) in a control mode according to an instruction from outside. The memory card interface mode complies with any of interface specifications for various standalone memory cards. For example, the interface controller uses program control to implement a memory card controller function that supports the memory card interface specifications. A control program or firmware can be downloaded via a network and added to the interface controller so as to support an intended memory card interface specification later on. Further, license information can be acquired via a network to inhibit an intended control program from being executed. This makes it possible to disable an intended memory card interface specification later on.

The interface controller has the following functions. The interface controller recognizes a memory card interface control mode corresponding to a command interchanged with the outside via the external connection terminal 7 or corresponding to a bus state. The interface controller changes a bus width corresponding to the recognized memory card interface control mode. The interface controller converts a data format corresponding to the recognized memory card interface control mode. The interface controller has the power-on reset function. The interface controller controls the interface with the memory formed in the semiconductor chip 3F. The interface controller converts a power supply voltage.

As mentioned above, the memory card is provided with the projection 8 for reliably preventing the memory card from being inserted incorrectly. The memory card 1 may be inadvertently inserted into the card slot of the mobile phone in an incorrect orientation by reversing the front and the rear or the first and second surfaces. Such mishandling may bend the connector terminal in the card slot. The external connection terminal 7 of the memory card 1 may contact with an incompatible connector terminal to degrade or destroy a circuit in the semiconductor chips (3C and 3F). Such mishandling can easily occur because the memory card 1 according to the embodiment is especially small sized.

When inserting the memory card 1 into the card slot of the mobile phone, a user can find the position of the projection 8 at his or her fingertips to correctly identify the front and the rear or the first and second surfaces of the memory card 1. The projection 8 can help prevent an incorrect insertion but also remove the memory card 1 from the card slot. Since the memory card 1 is very small and thin, it is difficult to fast remove it from the card slot. In consideration forth is, one end of the memory card 1 is provided with the projecting 8 thicker than the other parts. When the memory card 1 is inserted into the card slot, the thick projection 8 is not inserted into the card slot and is exposed outside. The user can hold and pull the projection 8 between his or her fingers to fast remove the memory card 1 from the card slot. The projection 8 functions as both preventing incorrect insertion of the memory card 1 and easily removing it.

As shown in FIGS. 1 through 3, the memory card 1 is rounded with a large curvature radius at both corners of one side that becomes the front edge of the memory card 1 when inserted into the card slot of the mobile phone. The other side of the memory card 1 opposite the front edge becomes the rear edge when the memory card 1 is inserted into the card slot of the mobile phone. Both corners of the rear edge are not rounded with such a large curvature radius. The front and rear edges of the memory card 1 are shaped remarkably differently. When inserting the memory card 1 into the card slot, the user can easily identify the front edge of the memory card 1. Since the corners of the front edge are rounded with a large curvature radius, the memory card 1 can move flat rotatively when its front edge contacts with an inner wall of the connector. The user can smoothly insert the memory card 1 even though it is positioned at an incorrect angle horizontally. As shown in FIG. 4, the memory card 1 is tapered at one side of the memory card, i.e., at that identified as the front edge when the memory card 1 is inserted into the card slot of the mobile phone.

Since the front edge is tapered to be thinner than the other parts, the user can smoothly insert the memory card 1 into the card slot even though the memory card 1 is positioned at an incorrect angle vertically.

As shown in FIGS. 1 and 5, the memory card is provided with a stepped guide recess 11 at both sides. The guide recess 11 is formed along the side of the mold resin 4 on the first surface of the memory card 1. The guide recess 11 is 0.55 mm wide and high. The guide recesses 11 are provided at both sides on the first surface of the memory card 1. Consequently, the width of the memory card on the first surface is smaller than the width on the back surface by 1.1 mm (0.55 mm×2). The guide recess 11 is used as a mechanism that prevents the memory card 1 from being inserted into the card slot of the mobile phone with the first and second surfaces upside down. As shown in FIGS. 1 through 3, one notch 12 is provided at each of both sides of the memory card 1. A locking recess 13 is provided at one side of the memory card 1. The notch 12 is used as a mechanism for preventing the external connection terminal 7 from incorrectly contacting with an incompatible terminal when the memory card is inserted into or is removed from the card slot of the mobile phone. The 18 locking recess 13 is used as a mechanism that prevents the memory card 1 from easily slipping out of the card slot.

The guide recess 11, the notch 12, and the locking recess 13 are not limited to those shown in the drawings with respect to the position, shape, and quantity, but can be variously designed.

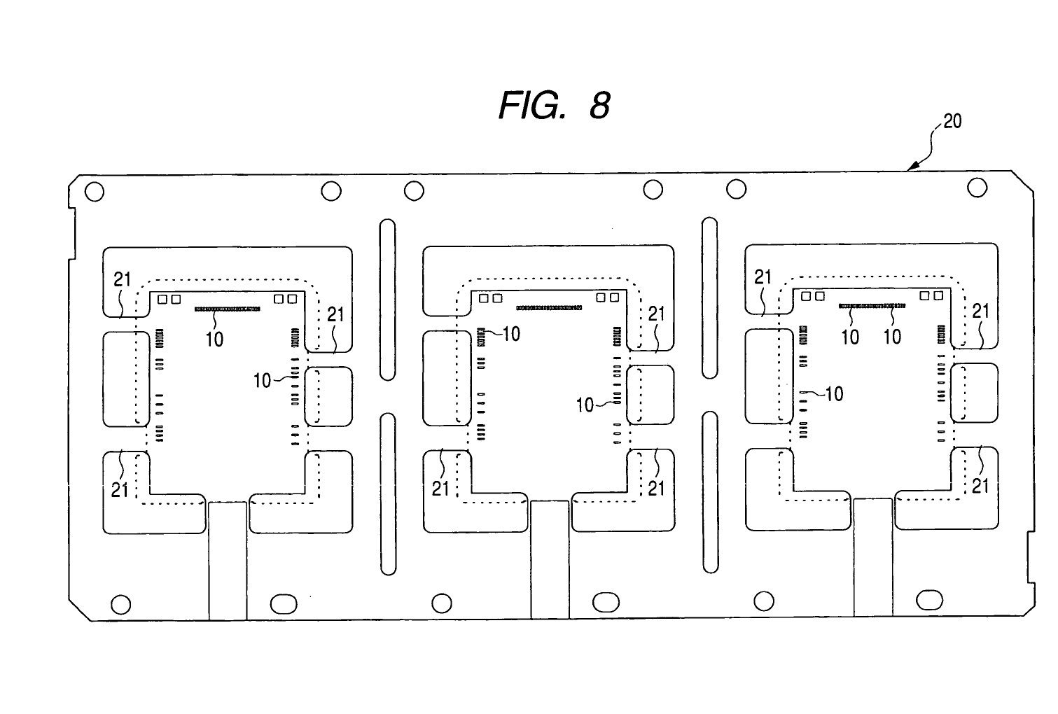

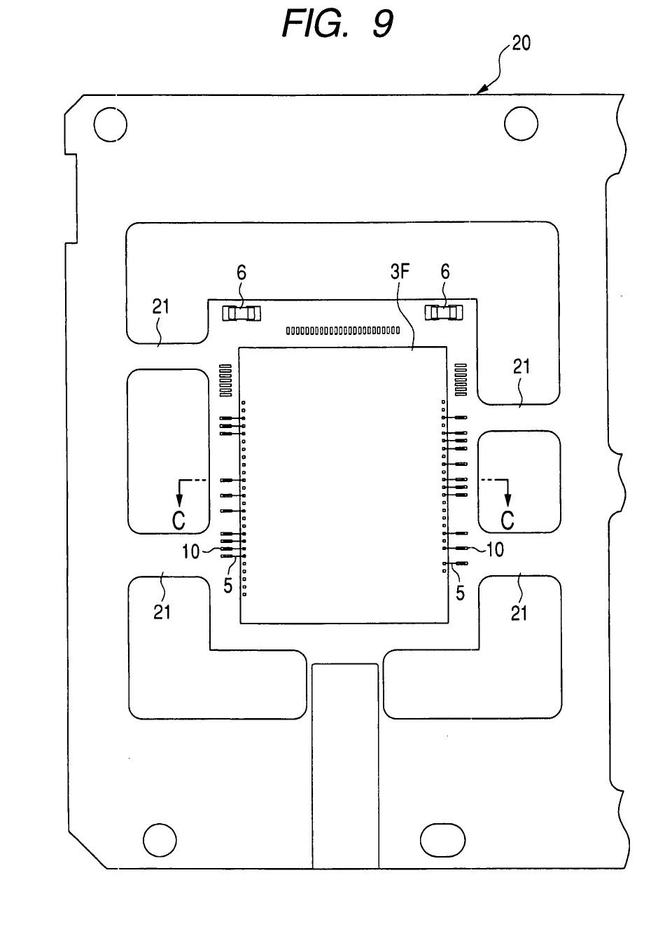

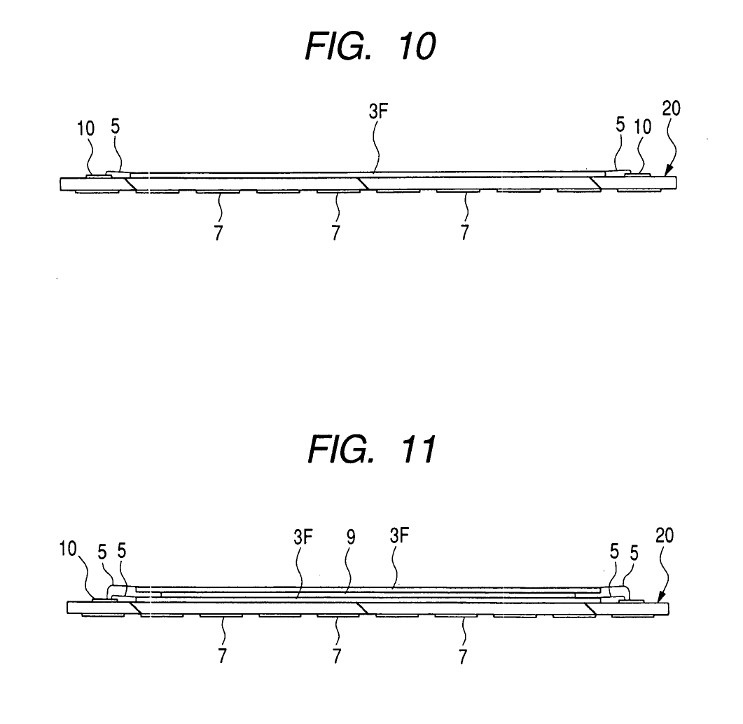

The following describes a manufacturing method of the memory card 1 according to the embodiment. FIG. 8 is a plan view showing a large wiring board 20 used to manufacture the memory card 1. The large wiring board 20 forms multiple units of patterns needed for the wiring board 2. In FIG. 8, a region enclosed in a dotted line is equivalent to one memory card 1. Accordingly, the large wiring board 20 in FIG. 8 can yield three memory cards 1. The large wiring board 20 contains a link portion 21 as well as the other units. The link portion 21 connects a region for the wiring board 2 of the memory card 1 with the other regions. The region for the wiring board 2 is surrounded by a space except the region for forming the link portion 21. The embodiment describes the manufacturing method using the large wiring board 20 capable of yielding three memory cards 1. Obviously, the manufacturing method can use a large wiring board capable of yielding four or more memory cards 1. FIG. 9 is a plan view showing one unit of the large wiring board 20. FIG. 10 is a cross sectional view taken along line 19 C-C of FIG. 9. To manufacture the memory card 1, as shown in FIGS. 9 and 10, the semiconductor chip 3F is mounted over each unit of the large wiring board 20. The wire 5 is then used to electrically connect the wiring 10 formed in the large wiring board 20 with the semiconductor chip 3F. The large wiring board 20 is mounted with a passive component such as the chip capacitor 6 as needed.

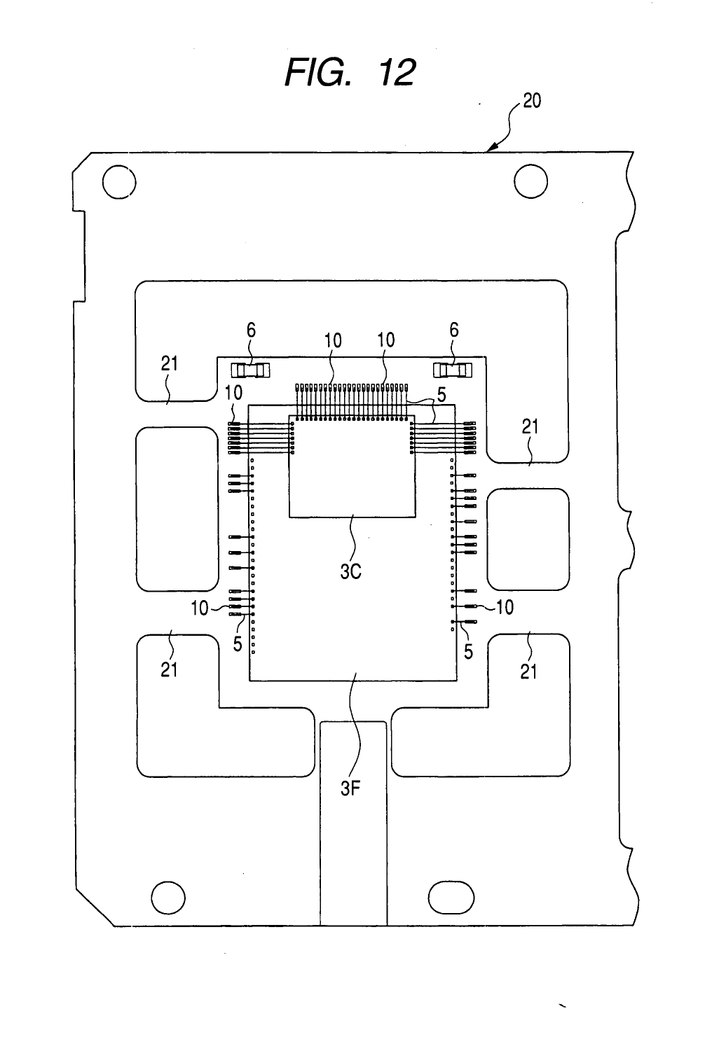

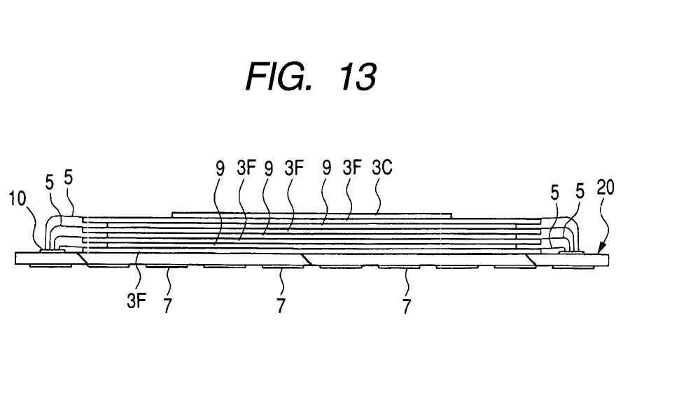

As shown in FIG. 11, the second semiconductor chip 3F is layered over the semiconductor chip 3F through the spacer chip 9. The wire 5 is then used to electrically connect the second semiconductor chip 3F with the wiring 10. The similar method is used to repeat layering of the spacer chip 9 and the semiconductor chip 3F and wire bonding. As shown in FIGS. 12 and 13, the semiconductor chip 3C is mounted over the top semiconductor chip 3F. The wire 5 is used to electrically connect the semiconductor chip 3C and the wiring 10.

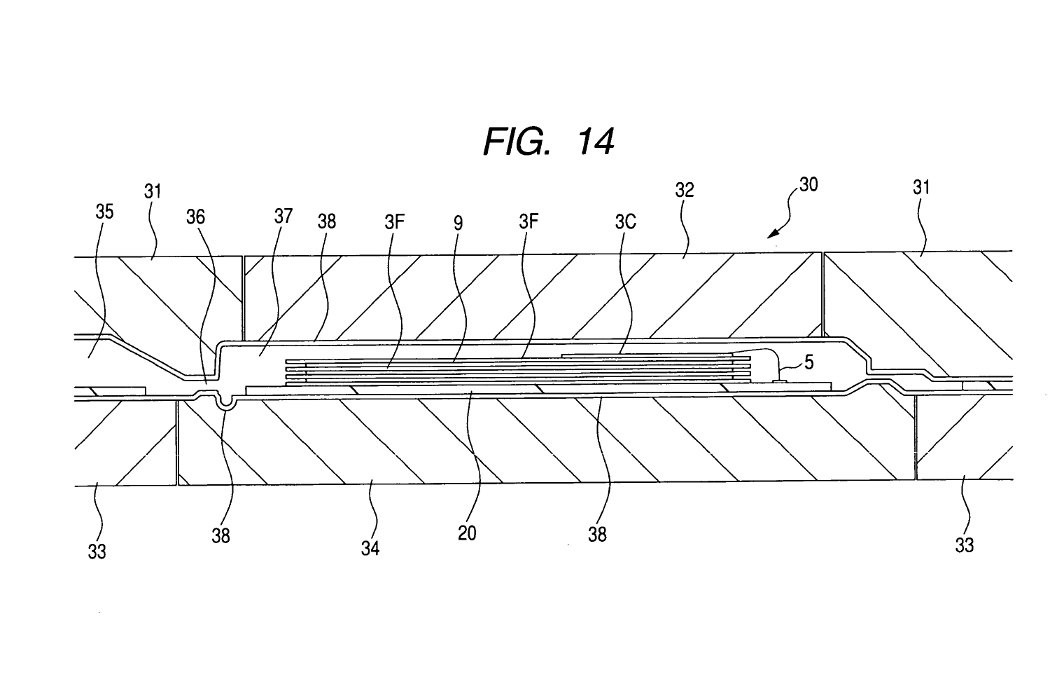

The large wiring board 20 is then attached to the mold resin die 30 as shown in FIG. 14. The mold resin die 30 includes an upper die 31, an upper die insert block 32, a lower die 33, and a lower die insert block 34. Regions denoted by reference numerals 35, 36, and 37 correspond to a runner, a gate, and a cavity, respectively. The upper die insert block 32 and the lower die insert block 34 are used as mechanisms for correcting a dimensional error of the cavity 37 in a thickness direction. Such error 20 may occur while the mold resin die 30 is manufactured. The mold resin die 30 is provided with the three cavities 37 corresponding to units of the large wiring board 20. When the mold resin die 30 is manufactured, however, dimensional variations may occur in the thickness direction of the three cavities 37. In such case, thicknesses of the three cavities 37 can be aligned by shifting the upper die insert block 32 or the lower die insert block 34 for any of the cavities 37. It is possible to provide the same thickness to the mold resins 4 for the three memory cards 1 that are produced from the mold resin die 30 at a time.

Part of the lower die insert block 34 is provided with a recess 39 for forming the projection 8 at one end of the memory card 1 so as to prevent the incorrect insertion as mentioned above. Providing the recess 39 for part of the lower die insert block 34 can form the projection 8 integrally with the mold resin 4 for encapsulating the wiring board 2 and the semiconductor chips (3C and 3F).

Laminated films 38 are attached to bottom surfaces of the upper die 31 and the upper die insert block 32 and to top surfaces of the lower die 33 and the lower die insert block 34 before the large wiring board 20 is attached to the mold resin die 30. The laminated film 30 is made of a thin resin sheet of several ten micrometers thick. One laminated film 38 is sucked by means of vacuum through a gap between 21 the upper die 31 and the upper die insert block 32. The laminated film 38 is attached firmly to the bottom surfaces of the upper die 31 and the upper die insert block 32. The other laminated film 38 is sucked by means of vacuum through a gap between the lower die 33 and the lower die insert block 34. The laminated film 38 is attached firmly to the bottom surfaces of the lower die 33 and the lower die insert block 34. These laminated films 38 are used for easily removing the resin (mold resin 4) injected into the cavity 37.

The upper die 31 and the lower die insert block 34 are tapered at one end of the cavity 37 that corresponds to the front edge of the memory card 1. This eliminates the need for a process of tapering the front edge of the memory card 1 by grinding the mold resin 4 after it is molded.

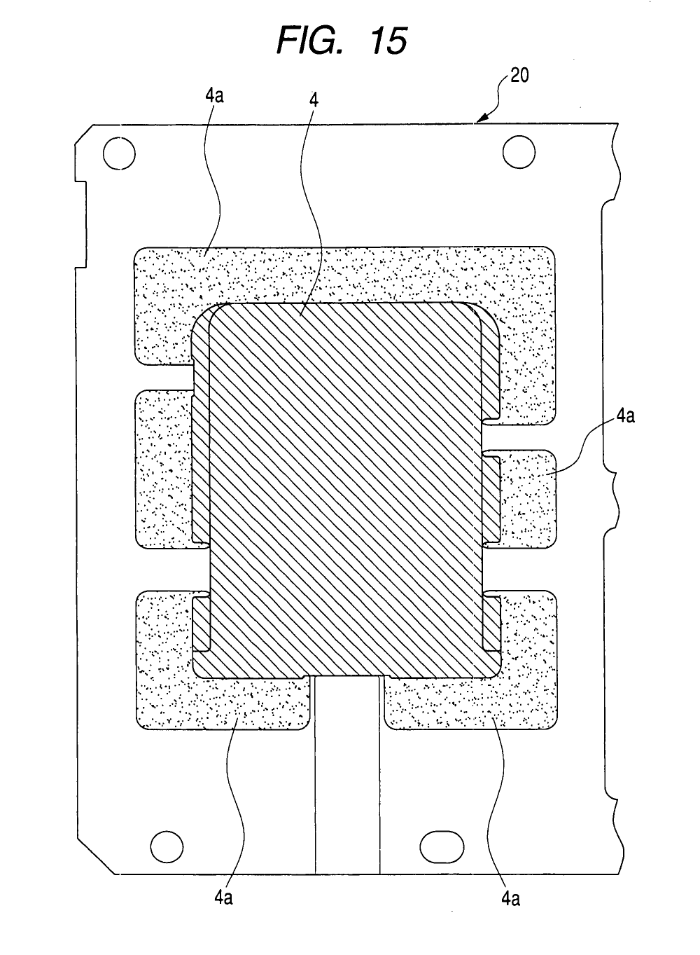

A melted resin is injected into the cavity 37 through the gate 36. The mold resin 4 encapsulates the wiring board 2 and the semiconductor chips (3C and 3F). The large wiring board 20 is then taken out of the mold resin die 30. FIG. 15 is a plan view showing one unit of the large wiring board 20. As mentioned above, the large wiring board 20 uses the link portion 21 to couple the region for the wiring board 2 of the memory card 1 with the other regions. The region for the wiring board 2 is surrounded by a space except the region for forming the link portion 21. 22

According to the structure of the mold resin die 30, a melted resin is injected into the cavity 37. Part of the melted resin overflows the cavity 37 to fill a resin burr 4a in the space. The resin burr 4a is approximately as thick as the large wiring board 20. The resin burr 4a is much thinner than the mold resin 4 that encapsulates the wiring board 2 and the semiconductor chips (3C and 3F).

In the resin molding using a mold resin die, injecting the melted resin into the cavity generally evaporates a volatile matter content or a moisture contained in the resin. A void is formed in the inside or on the surface of the mold resin. To prevent this, the mold resin die is partly provided with an air vent (air relief recess) or a flow cavity (disposable cavity) for transferring the volatile matter content or the moisture from the cavity to the outside.

On the other hand, the mold resin die 30 according to the embodiment is so structured that part of the melted resin overflows the cavity 37 and is filled into the surrounding space. The volatile matter content or the moisture contained in the melted resin is discharged outside the cavity 37 together with part of the melted resin. There is no need to provide the air vent or the flow cavity to part of the mold resin die 30. The die structure can be simplified. Thereafter, the resin burr 4a and the link portion 21 around the mold resin 4 are cut and processed to complete the memory card 1 according to the embodiment as shown in FIGS. 1 through 5.

As described in Japanese patent laid-open No. 2005-339496, the memory card according to a conventional technology includes the card body and the cap for housing it. Differently from such conventional memory card, the memory card according to the embodiment is constructed only as the card body including the wiring board 2, the semiconductor chips 3C and 3F provided for its main surface, and the mold resin 4 for encapsulating the wiring board 2 and the semiconductor chips 3C and 3F.

A thickness of the memory card according to the conventional technology depends on the sum of a card body thickness and a cap thickness. On the other hand, a thickness of the memory card 1 according to the embodiment depends only on a thickness of the part equivalent to the conventional card body. It is possible to mount many memory chips equivalent to the cap thickness and therefore provide a large capacity memory card. When the number of mounted memory chips is unchanged, the memory card can be thinned correspondingly to the cap thickness.

Since no cap is used, there is no need for a process of housing the card body in a cap recess after resin molding and of bonding both with an adhesive. The memory card manufacturing process can be simplified. The use of no cap decreases the number of parts. It is also possible to reduce material costs, shorten a manufacturing period, and simplify the process management.

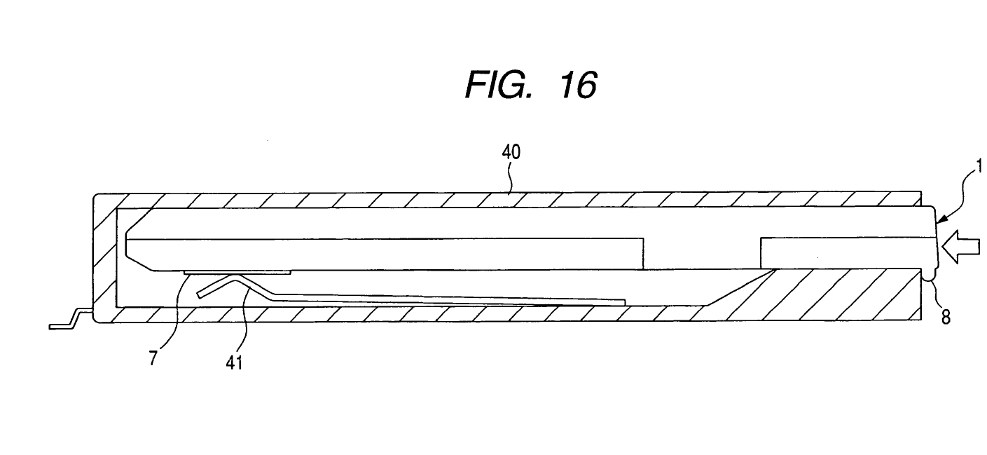

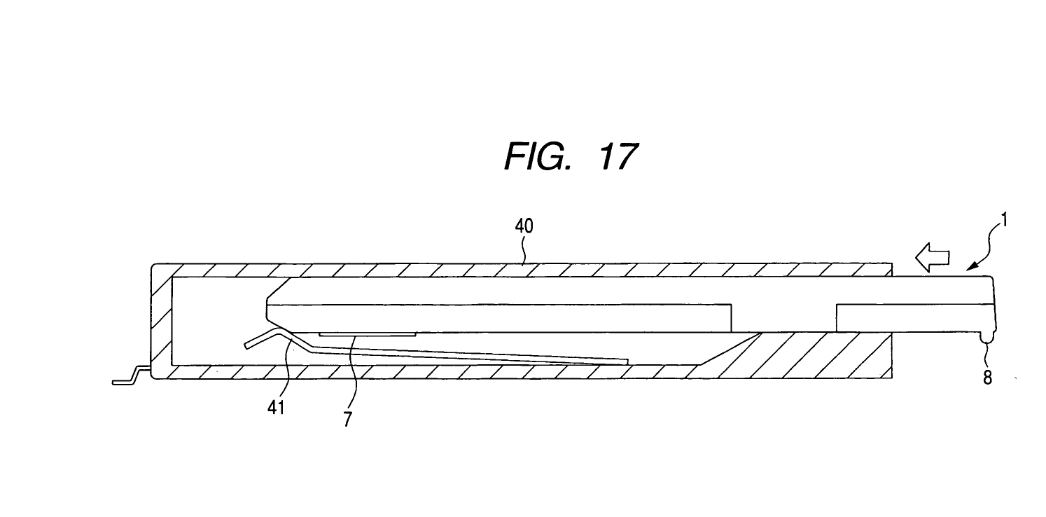

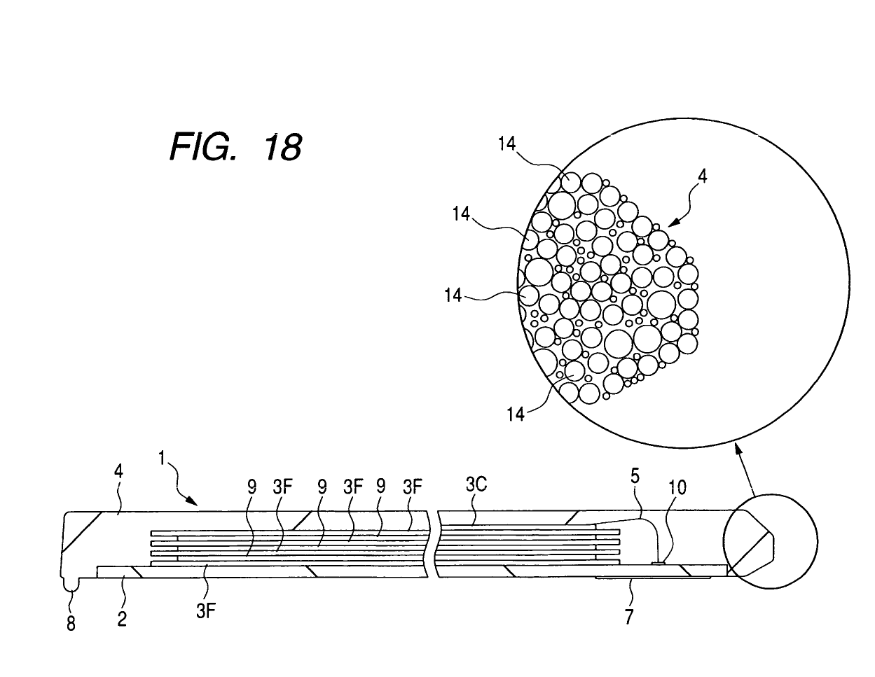

According to the prior art, multiple semiconductor chips are mounted on a large wiring board that forms multiple units of wiring patterns needed for wiring boards. A mold resin encapsulates the semiconductor chips at a time. A dicing blade is used to cut the large wiring board and the mold resin into units to manufacture individual card bodies. By contrast, the embodiment forms the mold resin 4 and then simply cuts and removes the link portion 21 and the resin burr 4a of the large wiring board 20. The cutting process can be simplified. The card slot of the mobile phone contains a connector 40 as shown in FIG. 16. The memory card 1 connects with the mobile phone when the memory card 1 is inserted into the connector 40 and the external connection terminal 7 of the memory card 1 contacts with a terminal 41 of the connector. When the memory card 1 is inserted into the connector, the tapered front edge of the memory card 1 first contacts with the terminal 41 as shown in FIG. 17. When the memory card 1 is further inserted, the memory card 1 presses the terminal 41 downward to contact with the external connection terminal 7.

A large quantity of filler such as quartz filler is mixed into the mold resin 4 used as a material for encapsulating the semiconductor chips (3C and 3F) so as to decrease a thermal expansion coefficient difference between the mold resin 4 and the semiconductor chips (3C and 3F). The resin mold containing a large quantity of inorganic filler provides a larger friction resistance to the terminal 41 and a higher hardness than a resin mold that contains no or a small quantity of filler. When the memory card 1 is repeatedly inserted into the connector 40, the mold resin 4 scrapes the surface of the terminal 41 to gradually degrade it. The terminal 41 may be deformed or damaged.

As a countermeasure, the card body of the memory card according to the prior art is covered with a cap made of a thermoplastic resin not as hard as the mold resin. This structure prevents the mold resin having a large friction resistance and a high hardness from being exposed at the front edge of the memory card.

As mentioned above, the front edge of the memory card 1 according to the embodiment is tapered by tapering the cavity 37 of the mold resin die 30. The mold resin 4 including the front edge of the memory card 1 shows approximately 10 through 15 [μm] of surface roughness Rz (Rmax) . The reason follows. When the resin is injected into the cavity 37 of the mold resin die 30, the filler contained in the resin is arranged along an inner wall of the cavity 37. As shown in FIG. 18, the exposed filler 14 forms a finely corrugated surface on the mold resin 4. In the memory card 1 according to the embodiment, an area of the wiring board 2 is smaller than that of the mold resin 4. The wiring board 2 is not exposed to the front edge of the memory card 1. Since the mold resin 4 covers the side of the wiring board 2, the wiring board 2 does not contact with the terminal 41 in FIG. 17.

In the above description, Rz (Rmax) denotes a value prescribed in the JIS standard with respect to surface roughness. An Rz (Rmax) value indicates a maximum height of the surface roughness. The maximum height is indicated by Rz in JIS_B0601:2001 and by Rmax in JIS_B0601:1987.

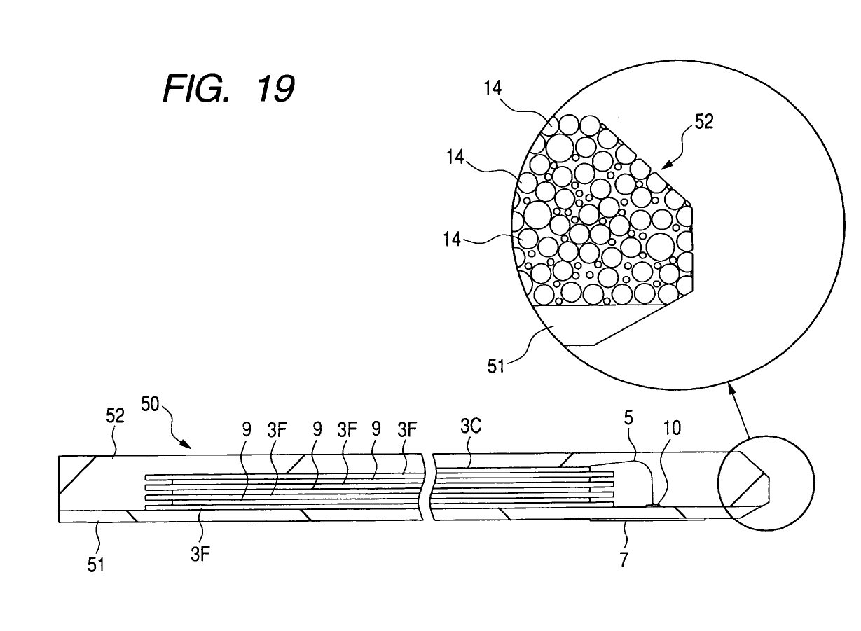

According to the prior art, multiple semiconductor chips are mounted on a large wiring board that forms multiple units of wiring patterns needed for wiring boards. A mold resin encapsulates the semiconductor chips at a time. A dicing blade is used to cut the large wiring board and the mold resin into units to manufacture individual card bodies. After the card body is manufactured according to this method, the front edge of the card body is ground and tapered. The front edge thereof is provided with a flat surface having approximately 3 through 5 [μm] of surface roughness Rz (Rmax). This is because a wiring board 51 and a mold resin 52 exposed to the front edge of a card body 50 are scraped and sharply edged as shown in FIG. 19. When the flat surface is formed at the front edge of the card body 50, inserting the card body 50 into the connector 40 causes a large contact area between the card body 50 and the terminal 41. The mold resin 52 scrapes the surface of the terminal 41 and easily degrades the terminal 41. In the example of FIG. 19, the side of the wiring board 51 is exposed. The wiring board 51 directly contacts with the terminal 41. Since the wiring board 51 is harder than the mold resin 52, the surface of the terminal 41 more easily degrades.

In the memory card 1 according to the embodiment, the mold resin 4 covers the side of the wiring board 2. Further, the material with large surface roughness is used for the front edge of the mold resin 4. The terminal 41 can be protected against degradation even when the memory card 1 is repeatedly inserted into the connector 40 of the mobile phone. Accordingly, the terminal 41 and the external connection terminal 7 can maintain reliable connection therebetween for a long time.

### SECOND EMBODIMENT

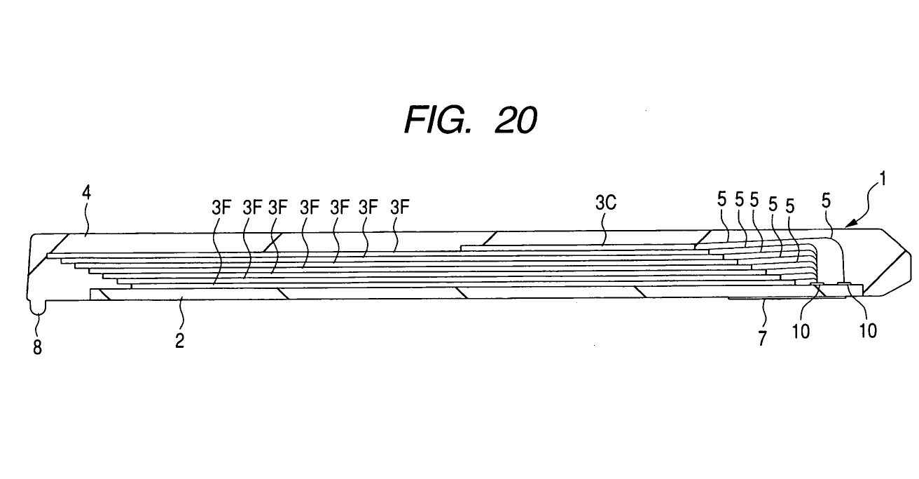

FIG. 20 is an example of layering the semiconductor chips 3F by shifting them over the main surface of the wiring board 2 so as not to cover a wire bonding region of the semiconductor chip 3F for a lower layer with the semiconductor chip 3F for an upper layer. This example eliminates the need to provide the dummy chip (space chip 9) between the semiconductor chips 3F for the upper and lower layers as described in the above-mentioned embodiment. Much more semiconductor chips 3F can be mounted.

The semiconductor chip 3C constituting the interface controller may be layered over the semiconductor chip 3F or may be mounted directly on the main surface of the wiring board 2. Obviously, the memory chip (semiconductor chip 3F) may contain not only semiconductor memory other than the flash memory but also a mixture of the flash memory and the other semiconductor memory.

The memory card manufacturing method according to the invention can make the size of the mold resin 4 larger than that of the wiring board 2 vertically and horizontally. As shown in FIG. 20, the semiconductor chips 3F can be mounted over the wiring board 2 so that the edges of the semiconductor chips 3F overhang outside the edge of the wiring board 2 at the rear of the memory card 1.

The wiring board 2 can be mounted with a semiconductor chip having a larger area than that of the wiring board 2. That is, the semiconductor chip 3F can be mounted so that it overhangs outside the edges of the wiring board 2 at the front and the rear of the memory card 1.

The memory card manufacturing method according to the invention can mount a semiconductor chip having a larger area than conventional equivalents in the memory card having the same size as conventional equivalents. The manufacturing method can provide a large capacity memory card.

The semiconductor chip mounted over the main surface of the wiring board 2 is not limited to the combination of the memory chip (semiconductor chip 3F) and the controller chip (semiconductor chip 3C). For example, an IC card microcomputer chip as a security controller can be mixed with the memory chip and the controller chip to provide a large capacity multifunctional memory card having a security function as well as the memory function.

### THIRD EMBODIMENT

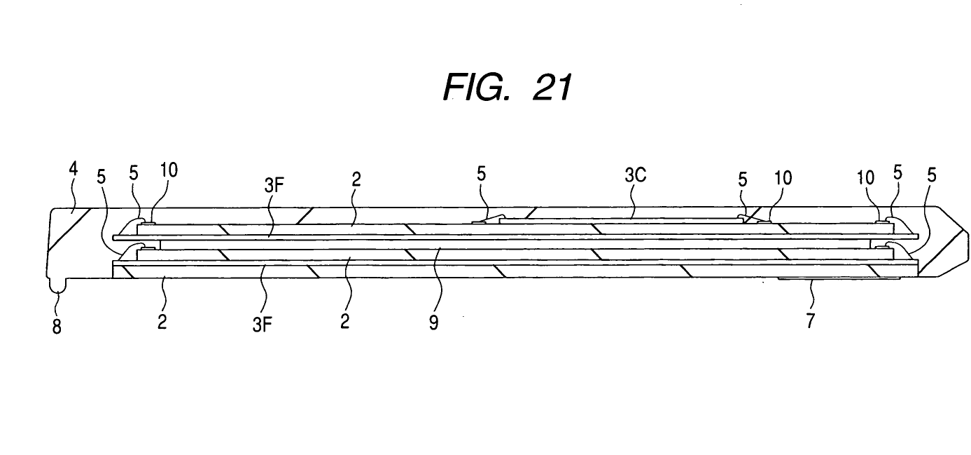

The first embodiment has described the example of using the semiconductor chip 3F having a smaller planar dimension than that of the wiring board 2. As shown in FIG. 21, it is possible to use the semiconductor chip 3F having the same planar dimension as that of the wiring board 2. The prior art does not form a mold resin over a region that exceeds the planar dimension of the wiring board. When a semiconductor chip has the same planar dimension as that of the wiring board, an edge of the semiconductor chip is not covered with the mold resin and is exposed. Accordingly, the prior art cannot adopt the construction according to the embodiment.

As mentioned in the first embodiment, the third embodiment can permit a region for forming the mold resin 4 to have a larger planar dimension than that of the wiring board 2. Even when the semiconductor chip 3F to be used has the same planar dimension as that of the wiring board 2, the mold resin 4 can cover edges of the semiconductor chip 3F. Even when the dimension is the same as conventional equivalents, the memory card can use the semiconductor chip 3F having a larger area than conventional equivalents. A large capacity memory card can be provided.

As shown in FIG. 20, another semiconductor chip 3F can be layered over the semiconductor chip 3F having the same planar dimension as the wiring board 2. In this case, the edge of the upper semiconductor chip 3F can overhang outside the edge of the wiring board 2 at the front of the memory card 1.

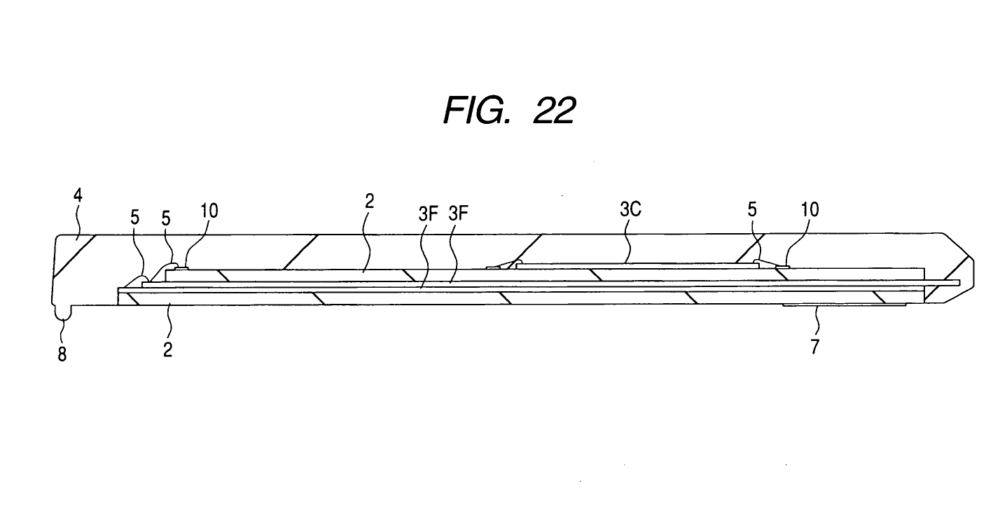

FIGS. 21 and 22 show the semiconductor chip 3F having the same planar dimension as that of the wiring board 2. It is possible to use the semiconductor chip 3F having a larger planar dimension than that of the wiring board 2 within the region covered with the mold resin 4. That is, the semiconductor chip 3F can be mounted so that it overhangs outside the edges of the wiring board 2 at the front and the rear of the memory card 1. This method can use the semiconductor chip 3F having a larger area and can provide a large capacity memory card.

While there have been described specific preferred embodiments of the present invention, it is to be distinctly understood that the present invention is not limited thereto but may be otherwise variously embodied within the spirit and scope of the invention.

The above-mentioned embodiments have described the memory card containing a layer of five semiconductor chips (four memory chips and one controller chip) mounted over the main surface of the wiring board. The invention is not limited to the number of layered semiconductor chips or the mounting modes that have been described.

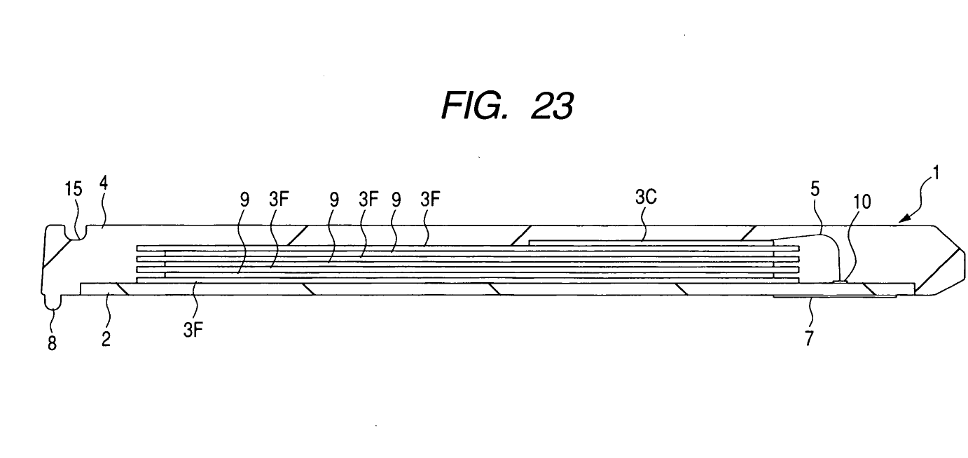

At one side of the memory card 1, the above-mentioned embodiments form the projection 8 to avoid incorrect insertion. As shown in FIG. 23, for example, a long recess 15 can be provided at a position opposite the projection 8 on the first surface of the memory card 1. This makes it possible to more easily remove the memory card 1 from a memory slot. In this case, it may be preferable to form a convex portion corresponding to the long recess 15 at part of the upper die insert block of the above-mentioned mold resin die 30. The long recess 15 can be formed integrally with the mold resin 4. Only the long recess 15 may be formed without forming the projecting 8.

The above-mentioned embodiments have described the memory card 1 in compliance with the Memory Stick Micro standard. The invention is not limited thereto but may be applicable to IC cards in compliance with the other standards.

The invention is applicable to a memory card to be attached to a card slot of a portable communication device.

What is claimed is:

1. A memory card comprising:
a wiring board;
a plurality of memory chips layered over a main surface of the wiring board;
a plurality of external connection terminals that are formed over a back surface of the wiring board and are electrically coupled with the memory chips; and
a mold resin that encapsulates the main surface of the wiring board and the memory chips, covers a side of the wiring board, and exposes a back surface of the wiring board.

2. The memory card according to claim 1,
wherein the memory chip includes a semiconductor chip forming a nonvolatile memory capable of electrical erasure and writing; and
wherein the main surface of the wiring board is further mounted with a semiconductor chip forming an interface controller that controls a memory interface operation for the nonvolatile memory.

3. The memory card according to claim 2,
wherein the main surface of the wiring board is further mounted with a semiconductor chip forming an IC card microcomputer as a security controller that performs a security process in accordance with an operation command supplied from the interface controller.

4. The memory card according to claim 1,
wherein the memory card is tapered at one side used as a front edge during card insertion so that the front edge becomes thinner than the other parts.

5. The memory card according to claim 1,
wherein the memory chips are mounted over the main surface of the semiconductor chip so that edges of the memory chips partly overhang outside an edge of the wiring board.

6. The memory card according to claim 1,
wherein the memory chips mounted over the main surface of the wiring board contain a memory chip having a larger area than the wiring board.

7. The memory card according to claim 1,
wherein a projection for prevention against incorrect insertion is formed at one side of the memory card used as a rear edge during card insertion.

8. The memory card according to claim 1,
wherein the mold resin has 10 through 15 of surface roughness in terms of Rmax according to a JIS_B0601:1987 standard.

9. The memory card according to claim 1,
wherein a size of the wiring board is smaller than that of the mold resin vertically and horizontally.

10. A manufacturing method for a memory card including a wiring board, a plurality of memory chips layered over a main surface of the wiring board, a plurality of external connection terminals that are formed over a back surface of the wiring board and are electrically coupled with the memory chips, and a mold resin that encapsulates the main surface of the wiring board and the memory chips, the method comprising the steps of:
(a) preparing a large wiring board forming a plurality of units of patterns needed for the wiring board;
(b) mounting the memory chips on the units of the large wiring board;
(c) after the step (b), attaching the large wiring board to a mold resin die, injecting a melted resin into a plurality of cavities provided for the mold resin die, and thereby forming the mold resin for encapsulating the memory chips correspondingly to units; and
(d) after the step (c), cutting and separating the mold resin and part of the large wiring board encapsulated by the mold resin from the large wiring board,
wherein, after the step (d), the mold resin is formed so as to cover a side of the wiring board and expose a back surface of the same.

11. The memory card manufacturing method according to claim 10,
wherein a chip mounting region corresponding to each of units for the large wiring board is coupled to the other regions of the large wiring board through a link portion;
wherein a space is formed around the chip mounting region except a region where the link portion is formed; and
wherein, when the melted resin is injected into the cavity at the step (c) , part of the melted resin is filled into the space.

12. The memory card manufacturing method according to claim 10,
wherein the mold resin has 10 through 15 of surface roughness in terms of Rmax according to a JIS_B0601:1987 standard.

13. The memory card manufacturing method according to claim 10,
wherein, before the step (c) , a resin sheet is attached to an inner wall of the cavity so as to easily separate the mold resin from the mold resin die.

14. The memory card manufacturing method according to claim 10,
wherein part of an inner wall of the cavity is tapered to taper the memory card at one side used as a front edge during card insertion so that the front edge becomes thinner than the other parts.
